(19) United States
(12) Patent Application Publication
(10) Pub. No.: US 2012/0064266 A1
(43) Pub. Date: Mar. 15, 2012

(54) HOUSING AND METHOD FOR MANUFACTURING HOUSING

(75) Inventors: HSIN-PEI CHANG, Tu-Cheng (TW); WEN-RONG CHEN, Tu-Cheng (TW); HUAN-WU CHIANG, Tu-Cheng (TW); CHENG-SHI CHEN, Tu-Cheng (TW); ZHI-JIE HU, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/968,403

(22) Filed: Dec. 15, 2010

(30) Foreign Application Priority Data
Sep. 15, 2010 (CN) 201010284860.4

(51) Int. Cl. B32B 15/04; B05D 3/00; C23C 14/06; B05D 3/14

(52) U.S. Cl. 428/34.6; 427/532; 204/192.15

(57) ABSTRACT

A housing includes a substrate; and a corrosion resistance layer deposited on the substrate. The corrosion resistance layer is a cerium oxide doped silicon nitride layer.

### CROSS-REFERENCE TO RELATED APPLICATIONS

The present application is related to co-pending U.S. Patent Applications (Attorney Docket No. US34388, US34392), entitled “HOUSING AND METHOD FOR MANUFACTURING HOUSING”, by Zhang et al. These applications have the same assignee as the present application and have been concurrently filed herewith. The above-identified applications are incorporated herein by reference.

### BACKGROUND

1. Technical Field

The exemplary disclosure generally relates to housings and a method for manufacturing the housings.

2. Description of Related Art

With the development of wireless communication and information processing technology, portable electronic devices, such as mobile telephones and electronic notebooks are now in widespread use. Physical vapor deposition (PVD) has conventionally been used to form a coating on a housing of portable electronic device, to improve the abrasion resistance of the housing of the portable electronic device. However, typical housing has a lower corrosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 illustrates a cross-sectional view of an exemplary embodiment of a housing.

FIG. 2 is a schematic view of a magnetron sputtering coating machine for manufacturing the housing in FIG. 1.

### DETAILED DESCRIPTION

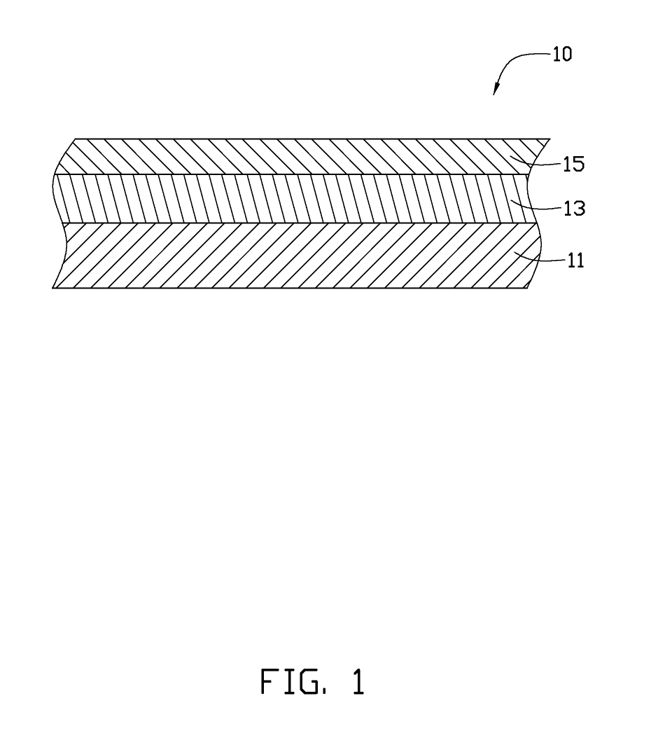

Referring to FIG. 1, an exemplary housing 10 includes a substrate 11 and a corrosion resistance layer 13 deposited on the substrate 11. The substrate 11 may be made of metallic materials, such as aluminum, aluminum alloy, magnesium, or magnesium alloy. The housing 10 may be a housing of an electronic device. The corrosion resistance layer 13 is cerium oxide doped silicon nitride layer, which is comprised of cerium, silicon, nitrogen, and oxide. The erosion resistance layer 13 further includes ceramic graphic Silicon Nitride (Si3N4) and ceramic graphic Cerium (IV) oxide (CeO2). The corrosion resistance layer 13 has a thickness ranging from about 0.5 micrometer to about 3 micrometer. The corrosion resistance layer 13 may be deposited by magnetron sputtering or cathodic arc deposition. The housing 10 may includes a color layer 15 deposited on the corrosion resistance layer opposite to the substrate 11, to decorate the appearance of the housing 10.

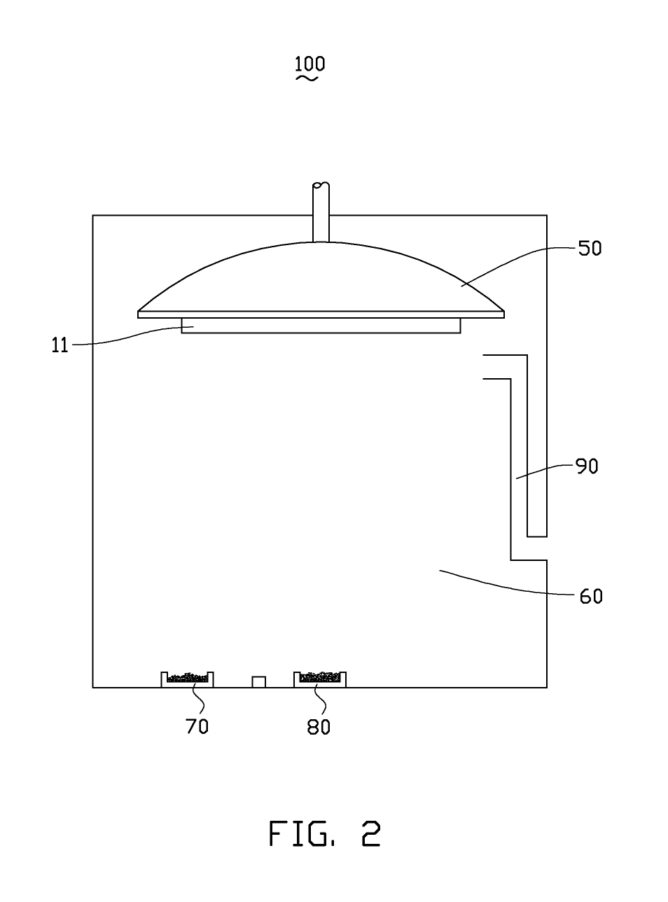

Referring to FIG. 2, a method for manufacturing the housing 10 includes the following steps.

A substrate 11 is provided. The substrate 11 may be made of metallic materials, such as, aluminum, aluminum alloy, magnesium or magnesium alloy.

The substrate 11 is pretreated. First, the substrate 11 is polished and electrolyzed to make the surface of the substrate 11 shine. The substrate 11 is then washed with a deionized water and an alcohol in turn. The substrate 11 is then washed with a solution (e.g., Acetone) in an ultrasonic cleaner, to remove grease, dirt, and/or other impurities. Second, the substrate 11 is dried. Third, the substrate 11 is retained on a rotating bracket 50 in a vacuum chamber 60 of a magnetron sputtering coating machine 100. The vacuum level of the vacuum chamber 60 is adjusted to 1.0×10-3 Pa, pure argon is floated into the vacuum chamber 60 at a flux of about 250 sccm to about 500 sccm from a gas inlet 90. A bias voltage is applied to the substrate 11 in a range from about −150 to about −500 volts for a time of about 5 min. to about 15 min. Then the substrate 11 is washed by argon plasma, to further remove the grease or dirt. Thus, the binding force between the substrate 11 and the corrosion resistance layer 13 is enhanced.

The corrosion resistance layer 13 is deposited on the substrate 11. The temperature in the vacuum chamber 60 is adjusted to 115˜350° C.; argon is floated into the vacuum chamber 60 at a flux from about 10 sccm to about 150 sccm and nitrogen is floated into the vacuum chamber 60 at a flux from about 40 sccm to about 150 sccm from the gas inlet 90; a silicon target 70 is evaporated in a power from about 50 to about 200 w and a cerium(IV) oxide (CeO2) target 80 is evaporated in a power from about 5 to about 30 w; a bias voltage applied to the substrate 11 is in a range from about −50 to about −115 volts for a time of about 90 to about 113 min, to deposit the corrosion resistance layer 13 on the substrate 11. During this stage, the silicon, the cerium(IV) oxide reacts to form ceramic graphic Silicon Nitride and ceramic graphic Cerium(IV) oxide. The ceramic graphic Silicon Nitride, the ceramic graphic Cerium(IV) oxide can prevent columnar crystal from forming in the color layer 13, to improve the compactness of the corrosion layer 13. Thus, the corrosion resistance of the housing 10 can be improved.

It is to be understood that the color layer 15 may be deposited on the corrosion resistance layer 13, to improve the appearance of the housing 10.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate; and
an corrosion resistance layer deposited on the substrate;
wherein the corrosion resistance layer is a cerium oxide doped silicon nitride layer.

2. The housing as claimed in claim 1, wherein the corrosion resistance layer is deposited by magnetron sputtering.

3. The housing as claimed in claim 1, wherein the substrate is made of aluminium, aluminium alloy, magnesium or magnesium alloy.

4. The housing as claimed in claim 1, wherein the corrosion resistance layer has a thickness ranging from about 0.5 micrometer to about 3 micrometer.

5. The housing as claimed in claim 1, further comprising a color layer deposited on the corrosion resistance layer opposite to the substrate, to decorate the appearance of the housing.

6. The housing as claimed in claim 1, wherein the corrosion resistance layer includes a ceramic graphic Silicon Nitride and a ceramic graphic Cerium(IV) oxide.

7. A method for manufacturing an housing comprises steps of:
providing a substrate; and
depositing an corrosion resistance layer on the substrate, wherein the corrosion resistance layer is a cerium oxide doped silicon nitride layer comprised of cerium, silicon, nitrogen and oxide.

8. The method of claim 7, wherein during depositing the corrosion resistance layer on the substrate, the substrate is retained in a vacuum chamber of a magnetron sputtering coating machine; the temperature in the vacuum chamber is adjusted to 115˜350° C.; argon is floated into the vacuum chamber at a flux from about 10 sccm to about 150 sccm and nitrogen is floated into the vacuum chamber at a flux from about 40 sccm to about 150 sccm; a silicon target is evaporated in a power from about 50 to about 200 w and a Cerium(IV) oxide target is evaporated in a power from about 5 to about 30 w; a bias voltage applied to the substrate 11 is in a range from −50 to −115 volts for a time of about 90 to about 113 min, to deposit the corrosion resistance layer on the substrate.

9. The method of claim 7, wherein further including a step of pretreating the substrate between providing the substrate and depositing an corrosion resistance layer on the substrate, the step of pretreating the substrate includes a first step which the substrate is polished and electrolyzed to make the surface of the substrate shine.

10. The method of claim 9, wherein the substrate is then washed with a deionized water and an alcohol in turn after the substrate the substrate is polished and electrolyzed.

11. The method of claim 10, wherein the substrate is then washed with an acetone in an ultrasonic cleaner to remove grease, dirt, and/or impurities after the substrate is washed with the alcohol.

12. The method of claim 11, wherein the step of pretreating the substrate further includes a second step which the substrate is dried.

13. The method of claim 12, wherein the step of pretreating the substrate further includes a third step which the substrate is retained on a rotating bracket in a vacuum chamber of a magnetron sputtering coating machine; the vacuum level of the vacuum chamber is adjusted to 1.0×10-3 Pa, pure argon is floated into the vacuum chamber at a flux of about 250 sccm to 500 sccm; a bias voltage applied to the substrate 11 in a range from −150 to −500 volts for a time of about 5 to about 15 minutes, so the substrate is washed by argon plasma.
